(19) United States
(12) Patent Application Publication
(10) Pub. No.: US 2024/0379323 A1
(43) Pub. Date: Nov. 14, 2024

(54) CONTROL METHOD, CHARGED PARTICLE BEAM DEVICE, AND PROGRAM

(71) Applicant: HITACHI HIGH-TECH SCIENCE CORPORATION, Tokyo (JP)

(72) Inventors: Toshiyuki NAGAMINE, Tokyo (JP); Atsushi UEMOTO, Tokyo (JP); Tatsuya ASAHATA, Tokyo (JP); Xin MAN, Tokyo (JP)

(21) Appl. No.: 18/692,789

(22) PCT Filed: Sep. 28, 2021
(86) PCT No.: PCT/JP2021/035609

§ 371 Date: Mar. 15, 2024

(51) Int. Cl. H01J 37/22; H01J 37/26

(52) U.S. Cl. CPC H01J 37/222; H01J 37/26

(57) ABSTRACT

The present invention provides a control method for a charged particle beam device for irradiating a sample in which a plurality of layers is laminated with a focused ion beam to process a cross-section of the sample at a processing angle that is a prescribed angle. The control method includes: an image generation step for irradiating the sample with an electron beam, detecting secondary electrons or reflected electrons generated from the sample, and generating an observation image of a cross-section of the sample based on results of detection; an angle deviation calculation step for calculating the angle deviation between the angle of the cross-section and the processing angle based on the observation image; and a control step for controlling orientation of the sample or a direction of radiation with the electron beam so as to eliminate the angle deviation calculated in the angle deviation calculation step.

### CROSS REFERENCE

The present Application for Patent is a 371 national phase filing of International Patent Application No. PCT/JP2021/035609, by NAGAMINE et al., entitled “CONTROL METHOD, CHARGED PARTICLE BEAM DEVICE, AND PROGRAM,” filed Sep. 28, 2021, assigned to the assignee hereof, and expressly incorporated by reference herein.

### TECHNICAL FIELD

The present invention relates to a control method, a charged particle beam device, and a program.

### BACKGROUND ART

To observe a sample with a transmission electron microscope (TEM) or the like, a charged particle beam device for processing the sample into a shape suitable for observation is known (for example, Patent Document 1)

### DOCUMENT OF RELATED ART

### Patent Document

Patent Document 1: Japanese Patent Application Publication No. 2013-120714

### DISCLOSURE

### Technical Problem

When processing a sample with a layered structure, it is required that the sample be accurately processed laterally or perpendicularly with respect to the layers of the sample.

The present invention has been made in view of these circumstances, and the objective of the present invention is to accurately process a sample laterally or perpendicularly to a layer of the sample.

### Technical Field

(1) One aspect of the present invention is a control method for a charged particle beam device for irradiating a sample in which a plurality of layers is laminated, with a focused ion beam thereby processing a cross-section of the sample at a processing angle, which is a predetermined angle, the control method including: an image generation step of irradiating a sample with an electron beam, detecting secondary electrons or reflected electrons generated from the sample, and generating an observation image of a cross-section of the sample based on the results of detection; an angle deviation calculation step of calculating the angle deviation between the angle of the cross-section and the processing angle based on the observation image; and a control step of controlling orientation of the sample or the direction of radiation with the electron beam so as to eliminate the angle deviation calculated in the angle deviation calculation step.

(2) The control method of (1) above, wherein the observation image may include a plurality of layers including an observation target layer that is a layer of target of observation, the method may further include a thickness calculation step of calculating the thickness of the observation target layer based on an image of the cross-section, and the angle deviation step may calculate the angle deviation by θ=cos⁻¹ (Lm/Ld) where Ld represents the thickness of the observation target layer that is calculated, Lm represents a design value of thickness of the observation target layer, and θ represents the angle deviation.

(3) The control method of (1) above, further including: a first processing step of executing processing of a cross-section of the sample S while irradiating the sample S with the focused ion beam; a second processing step of determining that there is a layer change in case, two layers above and below or left and right are mixed and stopping processing in the first processing step, stopping the processing in the first processing step, to process a cross-section of the sample S by a predetermined amount with the focused ion beam; and a layer edge position calculation step of calculating a first layer edge position, which is a position of a layer change, based on the observation image obtained before the second processing step and a second layer edge position, which is a position of layer change, based on the observation image obtained after the second processing, in which the angle deviation calculation step may calculate the angle deviation by θ=tan−1 (Lf/Lp) where Lp represents a position deviation, which is the distance between the first layer edge position and the second layer edge position which are obtained in the layer edge position calculation step, Lf represents the predetermined amount, and θ represents the angle deviation.

(4) The control method of (1) above, including: a processing step of executing processing of a cross-section of the sample S while irradiating the sample S with the focused ion beam; a stopping step of determining that there is a layer change in case, two layers above and below or left and right are mixed in the observation image obtained during the processing step, and stopping the processing of the processing step; an image generation step of changing an acceleration voltage of the electron beam and generating a surface image and a transmission image of the sample as the observation images; and a layer edge position calculation step of calculating a first layer edge position, which is a position of layer change, based on the surface image and a second layer edge position, which is a position of layer change, based on the transmission image, in which the angle deviation calculation step may calculate the angle deviation by θ=tan⁻¹ (Lt/Lr) when Lr represents a position deviation, which is the distance between the first layer edge position and second layer edge position that are calculated in the layer edge calculation step, Lt represents an amount of transmission of the electron beam from the surface of the sample, and θ represents the angle deviation.

Another aspect of the present invention is a charged particle beam device including: a focused ion beam column that processes a cross-section of a sample in which a plurality of layers is laminated at processing angle which is a predetermined angle by irradiating the sample with a focused ion beam; an electron beam column that irradiates the sample with an electron beam; an electron detector that detects secondary electrons or reflected electrons generated from the sample; an observation image generation unit that generates an observation image that is an image of a cross-section of the sample based on a signal output from the electron detector; a calculation unit that calculates an angle deviation between the angle of the cross-section and the processing angle based on the image; and a correction unit that controls orientation of the sample or the direction of radiation with the electron beam so that the angle deviation calculated by the calculation unit can be eliminated.

(6) A further aspect of the present invention is a program causing a computer that controls a charged particle beam device that irradiates a sample, in which a plurality of layers are laminated, with a focused ion beam to process a cross-section of the sample at a processing angle, which is a predetermined angle, to execute processing operations of: irradiating the sample with an electron beam; detecting secondary electrons or reflected electrons generated from the sample; generating an observation image of a cross-section of the sample based on the results of detection; calculating angle deviation between an angle of the cross-section and the processing angle based on the observation image; and controlling orientation of the sample or a direction of radiation with the electron beam so that the angle deviation that is calculated can be eliminated.

### Advantageous Effects

As described above, according to the present invention, a sample can be processed laterally or perpendicularly with respect to a layer of the sample with high accuracy.

### DESCRIPTION OF RELATED ART

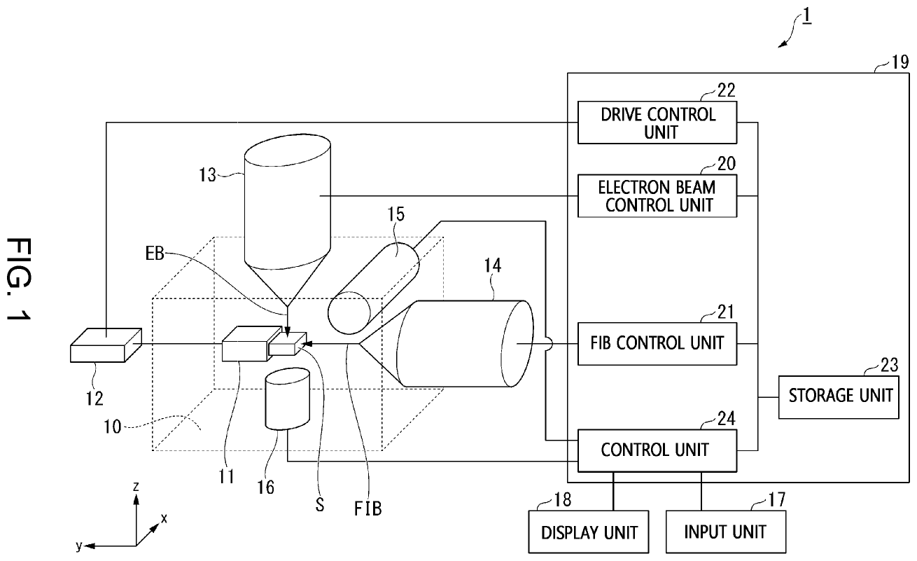

FIG. 1 is a diagram illustrating one example of the schematic configuration of a charged particle beam device according to one embodiment.

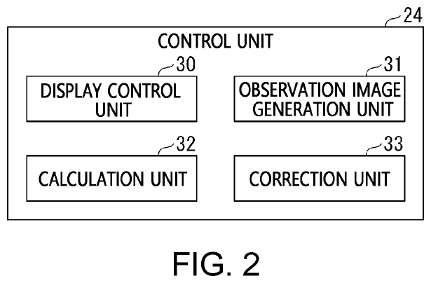

FIG. 2 is a diagram illustrating one example of the schematic configuration of a control unit according to one embodiment.

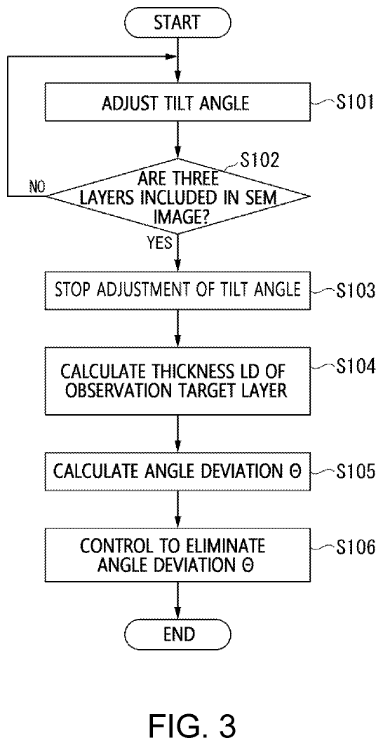

FIG. 3 is a flow diagram illustrating the flow of a first control method according to one embodiment.

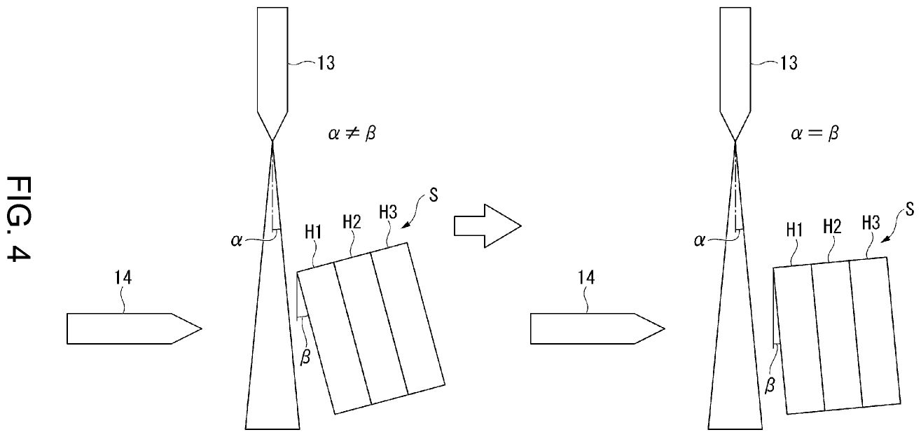

FIG. 4 is a diagram illustrating the first control method according to one embodiment.

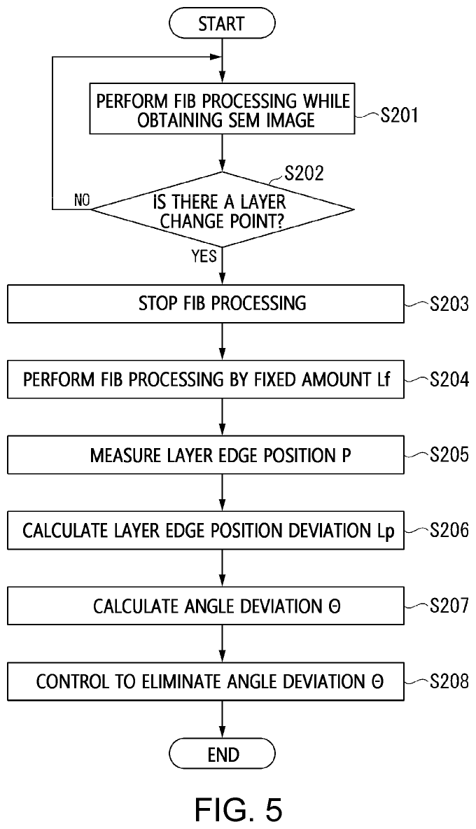

FIG. 5 is a flow diagram illustrating the flow of a first control method according to one embodiment.

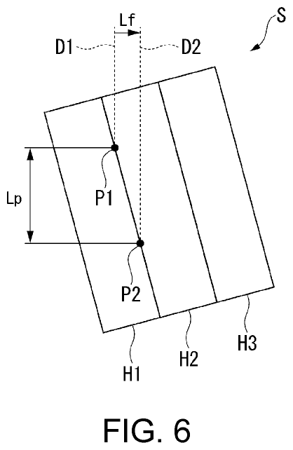

FIG. 6 is a diagram illustrating the second control method according to one embodiment.

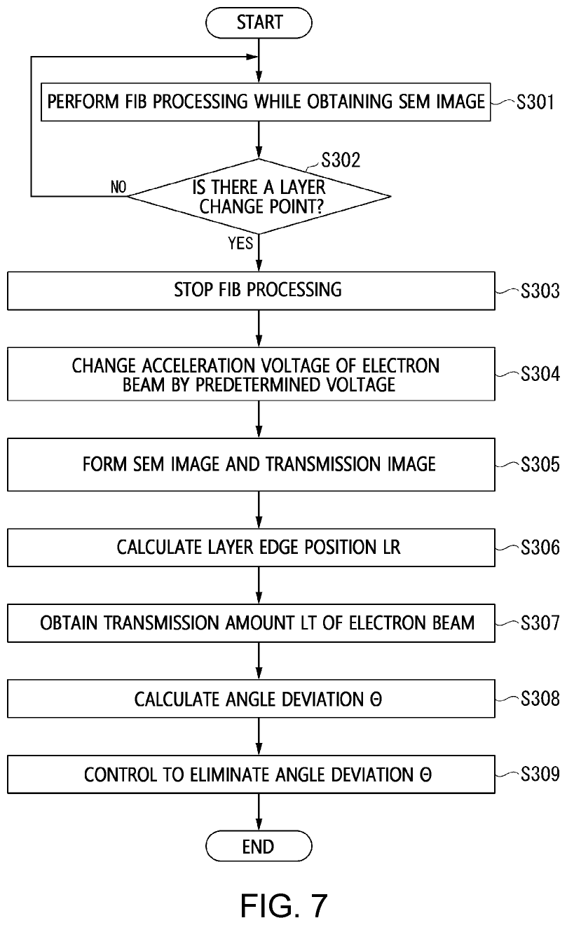

FIG. 7 is a flow diagram illustrating the flow of a first control method according to one embodiment.

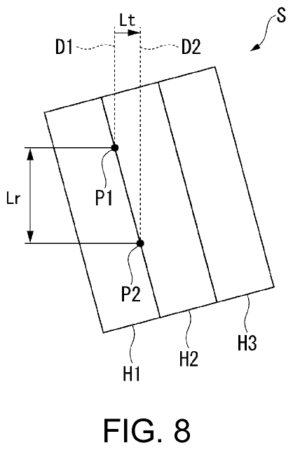

FIG. 8 is a diagram illustrating the third control method according to one embodiment.

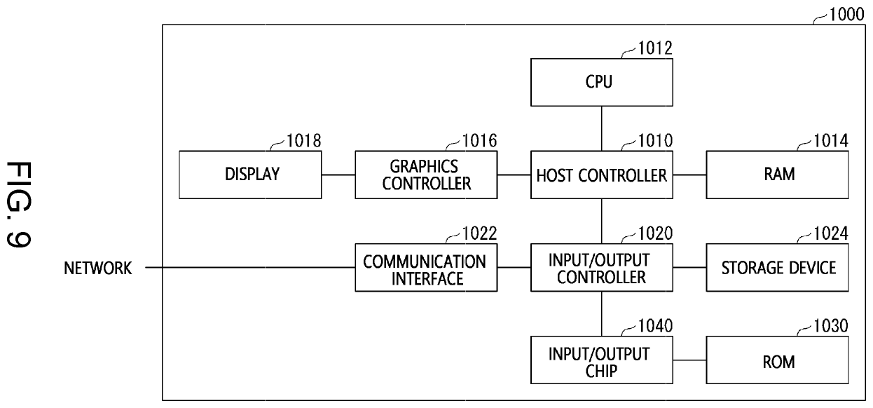

FIG. 9 is a hardware configuration view of a control device according to one embodiment.

### BEST MODE

Hereinafter, a charged particle beam device according to one embodiment will be described with reference to the accompanying drawings.

A charged particle beam device 1 irradiates a sample S in which a plurality of layers are laminated, with a focused ion beam, thereby processing a cross-section of the sample at a predetermined angle, which is a processing angle. When processing the sample S, the charged particle beam device 1 of the present embodiment calculates an angle deviation θ between a processing angle and the angle of a cross-section of the sample S (hereinafter referred to as “sample cross-section”) and corrects the orientation of the sample such that the calculated angle deviation θ can be eliminated. Therefore, the charged particle beam device 1 can accurately process the sample S laterally or perpendicularly with respect to a layer of the sample.

Here, the sample S is a sample in which a plurality of layers including the observation target layer are laminated in a predetermined lamination direction. The observation target layer is a layer made of an observation target material (for example, a semiconductor). In addition, aside from the multiple observation target layers, the sample S may have one or more non-observation target layers laminated in the lamination direction. The non-observation target layer is a layer made of a non-observation target material (for example, a metal conductor used as a power line or a signal transmission line). The sample S is, for example, a 3D-NAND flash memory. In this case, in the sample S, the observation target layers and the non-observation target layers are alternately laminated in the lamination direction. In addition, the lamination direction may be an arbitrary direction. Hereinafter, as an example, the case in which the lamination direction of the sample S disposed in a sample chamber 10 is an up-down direction. For convenience of explanation, for example, the case in which the sample S has a structure in which three layers are laminated will be described.

Hereinafter, the configuration of the charged particle beam device 1 is described in detail.

FIG. 1 is a diagram illustrating one example of the schematic configuration of the charged particle beam device 1 according to one embodiment. As illustrated in FIG. 1, the charged particle beam device 1 includes a sample chamber 10, sample stand 11, a drive mechanism 12, an electron beam column 13, a focused ion beam column 14, a secondary charged particle detector 15, a transmission electron detector 16, an input unit 17, a display unit 18, and a control device 19.

The sample chamber 10 is defined by an airtight, pressure-tight casing capable of maintaining the desired predetermined reduced pressure. The interior of the sample chamber 10 can be evacuated with an air exhauster (not shown) until the interior of the sample chamber 11 has the desired reduced pressure.

The sample stand 11 is a member to support the sample S and is disposed inside the sample chamber 10. The sample stand 11 is driven by the drive mechanism 12.

The drive mechanism 12 three-dimensionally translates and rotates the sample stand 11. The drive mechanism 12 moves the sample stand 11 backwards and forwards along each axial direction of X-axis, Y-axis, and Z-axis directions in the three-dimensional space., for example. The Z axis is the up-down direction and is orthogonal to a plane (XY plane) formed by the X axis and the Y axis. In addition, the drive mechanism 12 includes, for example, a tilt mechanism that rotates the sample stand around the X or Y axis and a rotation mechanism that rotates the sample stand around the Z axis. Hereinafter, the angle by which the sample stand 11 is rotated by the tilt mechanism is referred to as a tilt angle.

The electron beam column 13 irradiates the sample S disposed inside the sample chamber 10 with an electron beam (EB), which is an example of the charged particle beam. For example, the radiation direction of the electron beam is parallel to the Z-axis direction. In addition, for convenience of explanation, the direction parallel to the Z-axis direction is hereinafter referred to as the up-down direction, and the vertical direction of the up-down direction is referred to as the downward direction and the direction opposite to the vertical direction is referred to as the upward direction.

The focused ion beam column 14 irradiates the sample S disposed inside the sample chamber 10 with a focused ion (FIB). The cross-section of the sample S is thereby processed. In the following description, processing the sample S with a focused ion beam is sometimes referred to as “FIB processing”. The direction of radiation with the focused ion beam is, for example, parallel to the XY plane. In the example shown in FIG. 1, the direction of radiation with the electron beam column 13 and the direction of radiation with the focused ion beam column 14 are orthogonal to each other on the sample S. However, the invention is not limited thereto, and the focused ion beam column 14 may be arranged in the up-down direction or a tilt direction that is inclined with respect to the up-down direction.

The secondary charged particle detector 15 detects secondary electrons generated from the sample S irradiated with the ion beam or focused ion beam. The secondary charged particle detector 21 transmits the results of detection of the secondary electrons to the control device 19.

The transmission electron detector 16 detects transmission electrons passing through the sample S and an electron beam not incident on the sample S when the sample S is irradiated with an electron beam. The transmission electron detector 21 transmits the results of detection to the control device 19.

The input unit 17 is, for example, a mouse and keyboard that output signals corresponding to input operations made by the operator.

The display unit 18 displays various types of information of the charged particle beam device 1, image data generated based on signals output from the secondary charged particle detector 15, and screens for allowing operations such as zooming in, zooming out, moving, and rotating the image data.

The control device 19 controls the overall operation of the charged particle beam system 1. The control device 19 includes an electron beam control unit 20, a focused ion beam control unit (FIB control unit) 21, a drive control unit 22, a memory unit 23, and a control unit 24.

The electron beam control unit 20 outputs an irradiation signal to the electron beam column 13 based on the signals output from the control unit 24, thereby causing the electron beam column 13 to emit an electron beam.

The focused ion beam control unit 21 outputs an irradiation signal to the focused ion beam column 14 based on the signals output from the control unit 24, thereby causing the focused ion beam column 14 to emit a focused ion beam. The focused ion beam control unit 21 can adjust the direction of radiation with the focused ion beam emitted from the focused ion beam column 14 based on signals output from the control unit 24.

The drive control unit 22 controls the drive of the drive mechanism 12 based on the signals output from the control unit 24, and controls the orientation of the sample S by outputting a drive signal to the drive mechanism 12 to drive the sample stand 11. For example, the drive control unit 22 corrects the tilt angle by controlling the drive mechanism 12 so that the angle deviation θ calculated by the control unit 24 can be eliminated.

The memory unit 23 is equipped with a hard disk drive, flash memory, etc., and stores various types of information. The memory unit 23 stores information on the processing conditions for FIB processing. The charged particle beam device 1 performs scanning with a focused ion beam within a scanning area according to the processing conditions stored in the memory unit 23. This allows the charged-particle beam system 1 to perform etching of the scanning area and formation of an observation image of the scanning area using a focused ion beam. The processing conditions include scanning area information indicating the scanning area, information indicating the acceleration voltage of the electron beam, information indicating the beam current, information indicating the magnification, information indicating the contrast, information indicating the brightness, information indicating the thickness of a layer to be etched, information indicating the etching depth, information indicating the distance from the focused-ion beam column 14 to the surface of the sample S, etc.

FIG. 1 is a diagram illustrating one example of the schematic configuration of the control unit 24 according to one embodiment. The control unit 24 includes a display control unit 30, an observation image generation unit 31, a calculation unit 32, and a correction unit 33.

The display control unit 30 comprises a display device such as a liquid crystal display (LCD) device and displays transmission images or SEM images on the display unit 18.

The observation image generation unit 31 forms the transmission image based on an electron beam scanning signal of the electron beam control unit 20 and a signal of transmission electrons detected by the transmission electron detector 16. The observation image generation unit 31 forms data of the SEM image based on an electron beam scanning signal of the electron beam control unit 20 and the signal of secondary electrons detected by the secondary charged particle detector 15. The observation image in this embodiment may be an SEM image or may include both an SEM image and a transmission image.

The calculation unit 32 calculates the angle deviation e between the angle of the sample cross-section and the processing angle based on the pattern of the cross-section of the sample S shown in the SEM image.

The correction unit 33 communicates with the drive control unit 22 or the focused ion beam control unit 21 to control the orientation of the sample S or the direction of radiation with the focused ion beam so that the angle deviation θ calculated by the calculation unit 32 is eliminated. Specifically, the correction unit 33 may correct the tilt angle so that the angle deviation θ can be eliminated or may correct the direction of radiation with the focused ion beam by the scan rotation of the FIB. Based on the pattern of the cross-section of the sample S in the SEM image, the correction unit 33 may determine whether to correct the tilt angle or to correct the direction of radiation with the focused ion beam as a means of correcting the angle deviation θ so that the angle deviation θ can be eliminated.

Hereinafter, the flow of the method for controlling the charged particle beam device 1 is described in detail. First, the control method (first control method) for the case where the thickness Lm of the layer of the sample S is known will be described. FIG. 3 is a view illustrating an example of the first control method for eliminating the angle deviation θ in the charged particle beam device 1. FIG. 4 is a view illustrating the angle deviation θ to be corrected by the first control method.

The control device 19 controls the drive mechanism 12 to change the tilt angle so that three layers H1 to H3 of the sample S can appear in the SEM image (step S101). The control unit 24 determines whether the three layers appear in the SEM image generated by the observation image generation unit 31 (step S102). The control unit 24 outputs a stop command to the drive control unit 22 when it is determined that the three layers H1 to H3 appear in the SEM image generated by the observation image generation unit 31. Therefore, the drive control unit 22 stops the tilt angle adjustment by stopping the operation of the drive mechanism 12 (step S103). After the processing of step S103 is completed, the calculation unit 32 calculates the angle deviation θ based on the SEM image containing the three layers.

Here, it is assumed that among the three layers H1 to H3, the observation target layer is the middle layer H2 sandwiched between the two layers H1 and H3. The calculation unit 32 calculates the thickness of the observation target layers by performing known image processing on the SEM image (step S104). The thickness of the observation target layer calculated by the calculation unit 32 is denoted by “Ld”. The calculation unit 32 calculates the angle deviation θ between the angle β of the sample cross-section and the processing angle α by inputting the calculated thickness Ld of the observation target layer and the design value Lm of the thickness of the observation target layer into Formula (1) (Step S105). The actual thickness of the observation target layer is known, and the design value Lm is stored in advance in the control unit 24.

θ=cos⁻¹ (Lm/Ld) . . . Formula (1).

The correction unit 33 controls the orientation of the sample S or the direction of radiation with the focused ion beam so that the angle deviation θ calculated by the calculation unit 32 can be eliminated (Step S106). For example, when correcting the tilt angle to eliminate the angle deviation θ, the correction unit 33 controls the drive mechanism 12 to change the tilt angle by the amount of the angle deviation θ. On the other hand, when the direction of radiation with the focused ion beam is corrected to eliminate the angular misalignment θ, the correction unit 33 transmits information on the angle deviation θ to the focused ion beam control unit 21 and changes the direction of radiation with the focused ion beam by the amount of the angle deviation θ. For example, when the cross-section of the sample S is processed laterally with respect to the layers, and the SEM image of the cross-section of the sample S is divided into the current layer and the next layer disposed at the upper and lower sides when a layer change occurs, the correction unit 33 can eliminate the angle deviation θ by changing the tilt angle by the amount of the angle deviation θ. By this, the cross-section of the sample S can be processed laterally.

Next, the second control method for the case in which the actual thickness of the observation target layer is not known will be described. FIG. 5 is a view illustrating an example of the second control method for eliminating the angle deviation e in the charged particle beam device 1.

The control device 19 operates the electron beam column 13 to irradiate the sample S with an electron beam while the focused ion beam column 14 irradiates the sample S with a focused ion beam. The control device 19 then performs FIB processing while acquiring SEM images (step S201).

The control unit 24 determines in real time whether or not there is a layer change in the cross-section of the sample S based on the SEM image acquired during the FIB processing in step S201 (step S202). The control unit 24 determines that there is a layer change in case, two layers above and below or left and right are mixed in the pattern of the cross-section of the sample S in the SEM image. When it is determined that there is a layer change, the control unit 24 stops the emission of the focused ion beam, thereby stopping the FIB processing in step S201 (step S203).

Next, the control device 19 performs FIB processing by a fixed amount Lf (step S204). In other words, when the control device 19 determines that there is a change of layers, the process proceeds to the FIB processing for only a fixed amount of Lf (hereinafter referred to as “fixed-volume FIB processing”) from the process of step S201. The calculation unit 32 acquires the SEM image from the observation image generation unit 31 after performing the fixed-volume FIB processing and measures a layer edge position P based on the acquired SEM image (step S205). The fixed-volume FIB processing is executed one or more times, and the layer edge position P is measured each time the fixed-volume FIB processing is executed. The calculation unit 32 determines how much the layer edge position P is displaced by the execution of the fixed-volume FIB processing. In other words, the calculation unit 32 calculates the amount of change Lp in the layer edge position P (hereinafter referred to as “layer edge position deviation”) that is caused by the execution of the processing for the fixed-volume Lf (step S206).

For example, as shown in FIG. 6, the calculation unit 32 measures the layer edge position (first layer edge position) P1, which is the position at which a layer change from the layer H1 to the layer H2 occurs in the SEM image of the cross-section D1 of the sample. After the layer edge position P1 is measured, the fixed-volume FIB processing is executed to form the cross-section D2. When the cross-section D2 is formed, the calculation unit 32 measures the layer edge position (second layer edge position) P2, which is the position at which a layer change from the layer H1 to the layer H2 occurs in the SEM image of the cross-section D2. Then, the calculation unit 32 calculates the distance between the layer edge position P1 and the layer edge position P2 in the Z-axis direction as the layer edge position deviation Lp. When the layer edge position deviation Lp is obtained, the calculation unit 32 calculates the angle deviation θ using Formula (2) shown below (Step S207).

θ=tan⁻¹ (Lf/Lp) . . . Formula (2)

The correction unit 33 controls the orientation of the sample S or the direction of radiation with the focused ion beam so that the angle deviation θ calculated by the calculation unit 32 can be eliminated (Step S208). For example, the correction unit 33 may control the drive mechanism 12 to change the tilt angle by the angle deviation θ or to change the direction of radiation with the focused ion beam by the angle deviation e so that the angle deviation θ can be eliminated. For example, when the sample S is processed laterally with respect to the layers, and the SEM image of the sample S is divided into the current layer and the next layer disposed at the left and right sides when a layer change occurs, the correction unit 33 can eliminate the angle deviation e by changing the direction of radiation with the focused ion beam by the angle deviation θ. By this, the cross-section of the sample S can be processed laterally.

Next, the third control method for the case in which the actual thickness of the observation target layer is not known will be described.

The control device 19 operates the electron beam column 13 to irradiate the sample S with an electron beam while the focused ion beam column 14 irradiates the sample S with a focused ion beam. The control device 19 then performs FIB processing while acquiring SEM images (step S301).

The control unit 24 determines in real time whether or not there is a layer change in the cross-section of the sample S based on the SEM image acquired during the FIB processing in step S201 (step S302). The control unit 24 determines that there is layer change in case, two layers above and below or left and right are mixed in the pattern of the cross-section of the sample S in the SEM image. When it is determined that there is a layer change, the control unit 24 stops the emission of the focused ion beam, thereby stopping the FIB processing (step S303).

When the FIB processing is stopped, the control unit 24 transmits a signal to the electron beam control unit 20 to change the acceleration voltage of the electron beam by a predetermined voltage (step S304). The observation image generation unit 31 forms an SEM image and a transmission image after the acceleration voltage of the electron beam is changed by the predetermined voltage (step S305). The calculation unit 32 measures the layer edge position P in each of the SEM image and the transmission image, and calculates the distance in Z-axis direction between the layer edge position P1 in the SEM image and the layer edge position P2 in the transmission image as the layer edge position deviation Lr (step S306). The calculation unit 32 calculates the amount of transmission Lt (i.e., amount of transmission from the cross-sectional surface of the sample S) of the electron beam based on the processing conditions stored in the memory unit 23 (step S307). The amount of transmission Lt of the electron beam may be stored in advance in the memory unit 23.

For example, as shown in FIG. 7, the calculation unit 32 measures the layer edge position P1, which is a position at which a layer change from the layer H1 to the layer H2 occurs in the SEM image of the cross-section D1 of the sample. The calculation unit 32 measures the layer edge position P2, which is a position at which a layer change from the layer H1 to the layer H2 occurs, in the transmission image of the cross-section D2 of the sample. Then, the calculation unit 32 calculates the distance between the layer edge position P1 and the layer edge position P2 in the Z-axis direction as the layer edge position deviation Lr. The calculation unit 32 calculates the amount of transmission Lt of the electron beam based on the processing conditions stored in the memory unit 23.

The calculation unit 32 calculates the angular deviation θ using Formula (3) shown below (Step S308).

θ=tan⁻¹ (Lt/Lr) . . . Formula (3)

The correction unit 33 controls the orientation of the sample S so that the angle deviation e calculated by the calculation unit 32 can be eliminated (Step S308). For example, the correction unit 33 may control the drive mechanism 12 to change the tilt angle by the angle deviation e or to change the direction of radiation with the focused ion beam by the angle deviation θ so that the angle deviation θ can be eliminated. For example, when the sample S is processed laterally with respect to the layers, and the SEM image of the sample S is obliquely divided into the current layer and the next layer when a layer change occurs, the correction unit 33 can eliminate the angle deviation θ by adjusting at least either one of the tilt angle and the direction of radiation with the focused ion beam. By this, the cross-section of the sample S can be processed laterally.

As described above, the control method of the present invention is a control method for a charged particle beam device for processing a cross-section of a sample at a predetermined angle which is processing angle by irradiating a sample S in which a plurality of layers is laminated with a focused ion beam. In addition, the control method of the present invention includes: an image generation step of irradiating a sample S with an electron beam, detecting secondary electrons or reflected electrons generated from the sample S, and generating an observation image of a cross-section of the sample S based on the results of detection; an angle deviation calculation step of calculating an angle deviation θ between an angle of the cross-section and a processing angle based on the observation image; and a control step of controlling the orientation of the sample S or the direction of radiation with the electron beam so that the angle deviation θ calculated in the angle deviation calculation step can be eliminated.

Since the angle deviation θ can be eliminated with the configuration described above, the sample S with a layered structure can be processed with high accuracy, laterally or perpendicularly with respect to the layers of the sample S.

In addition, the control method of the present embodiment may further include a thickness calculation step of adjusting a tilt angle so that a plurality of layers including an observation target layer, which is the layer of target of observation are included in the observation image, and calculating the thickness of the observation target layer based on the observation image of the cross-section. In addition, in the angle deviation calculation step, the angle deviation θ may be calculated by Formula (1) in which Ld represents the calculated thickness of the observation target layer and Lm represents a design value of the thickness of the observation target layer.

With this configuration, the angle deviation θ can be calculated without processing the sample S.

In addition, the control method of the present embodiment may further include: a first processing step of processing the cross-section of the sample S while irradiating the sample S with a focused ion beam; a second processing step of determining that there is a layer change in case, two layers above and below or left and right are mixed in the observation image which can be obtained in the first processing step, stopping the first processing step, and processing the cross-section of the sample S by a predetermined amount with the focused ion beam; and a layer edge position calculation step of calculating a first layer edge position, which is a position at which a layer change occurs based on the observation image obtained before the second processing step and a second layer edge position, which is a position at which a layer change occurs, based on the observation image obtained after the second processing. The angle deviation calculation step may calculate the angle deviation θ using Formula (2) when the position deviation which is the difference between the first layer edge position and the second layer edge position which are calculated in the layer edge position calculation step, is Lp and the predetermined amount is Lf.

With the configuration described above, even though the layers of the sample S are not distinguishable, the angle deviation θ can be calculated, and the sample S with a layered structure can be processed with high accuracy, laterally or perpendicularly with respect to the layers of the sample S.

In addition, the control method of the present embodiment may include: a processing step of processing the cross-section of the sample S while irradiating the sample S with a focused ion beam; a stopping process of stopping the processing of the processing step when it is determined that there is a layer change in case, two layers above and below or left and right are mixed in the observation image obtained during the processing step; an image generation step of generating a surface image and a transmission image of the sample S as the observation images by changing an acceleration voltage of the electron beam; and a layer edge position calculation step of calculating a first layer edge position, which is a position of layer change, based on the surface image and a second layer edge position, which is a position of layer change, based on the transmission image. The angle deviation calculation step may calculate the angle deviation θ using Formula (3) when the position deviation, which is the difference between the first layer edge position and the second layer edge position which are calculated in the layer edge position calculation step, is set to Lr and an amount of transmission of the electron beam transmitted from the surface of the sample S is set to Lt.

With the configuration described above, even though the layers of the sample S are not distinguishable, the angle deviation θ can be calculated without processing the sample S, and the sample S with a layered structure can be processed with high accuracy, laterally or perpendicularly with respect to the layers of the sample S.

FIG. 9 schematically illustrates an example of a hardware configuration of a computer 1000 functioning as the control device 19. A program installed in the computer 1000 can cause the computer 1000 to function as one or more “units” of the control device 19 of the embodiment described above, can cause the computer 1000 to perform the operations associated with control device 19 of the embodiment or the one or more “units” of the control device 19, and/or can cause the computer 1000 to perform the process associated with the embodiment or the steps of the process. Such a program may be executed by a CPU 1012 to cause the computer 1000 to perform specific operations associated with some or all of the blocks in the flowcharts and block diagrams described herein.

The computer 1000 in the embodiment includes the CPU 1012, a random access memory (RAM) 1014, and a graphics controller 1016, which are interconnected to each other by a host controller 1010. The computer 1000 also includes input/output units such as a communication interface 1022 and a storage device 1024, and the input/output units are connected to the host controller 1010 via an input/output controller 1020. The storage device 1024 may be a hard disk drive, a solid state drive, etc. The computer 1000 also includes a read only memory (ROM) 1030 and an input/output unit such as a touch panel, and the ROM 1030 and the input/output unit are connected to the input/output controller 1020 via an input/output chip 1040.

The CPU 1012 operates in accordance with the programs stored in the ROM 1030 and the RAM 1014, thereby controlling each unit. The graphics controller 1016 obtains image data generated by the CPU 1012 from a frame buffer or the like provided in the RAM 1014 or built within itself so that the image data can be displayed on the display device 1018.

The communication interface 1022 communicates with other electronic devices via a network. The storage device 1024 stores programs and data to be used by the CPU 1012 provided in the computer 1000.

The ROM 1030 stores therein programs such as a boot program to be executed by the computer 1000 upon activation and/or programs that are dependent on the hardware of the computer 1000. The input/output chip 1040 may also connect various input/output units to the input/output controller 1020 via USB ports, parallel ports, serial ports, keyboard ports, mouse ports, etc.

The program is provided by means of a computer-readable storage medium such as an IC card. The program is read out of a computer-readable storage medium, installed into the storage device 1024, the RAM 1014, or the ROM 1030, each of which is an example of a computer-readable storage medium, and executed by the CPU 1012. The information processing described within these programs is read by the computer 1000 and results in linkages between the programs and the various types of hardware resources described above. The device or method may be configured by executing the operation or processing of information according to the use of the computer 1000.

For example, when communication is performed between the computer 1000 and an external device, the CPU 1012 may execute a communication program loaded into the RAM 1014 and instruct the communication interface 1022 to perform communication processing based on the processing described in the communication program. Under the control of the CPU 1012, the communication interface 1022 reads transmission data stored in a transmission buffer area provided on a recording medium such as the RAM 1014, the storage device 1024, or an IC card, transmits the read transmission data to the network, or records reception data received from the network in a reception buffer area provided on the recording medium, etc.

In addition, the CPU 1012 may also perform various types of processing on data stored in the RAM 1014 so that the entirety or part of a database or file stored in the storage device 1024 or an external recording medium such as an IC card are read by RAM 1014. The CPU 1012 may then write back the processed data to the external storage medium.

Various types of information, such as various types of programs, data, tables, and databases, may be stored on a recording medium and undergo information processing. The CPU 1012 may perform various types of processing including various type of operations, information processing, conditional determinations, conditional branching, unconditional branching, information retrieval/replacement, etc., as specified by the program instruction sequence described elsewhere in the present disclosure, on the data read out of the RAM 1014 and the CPU 1012 may write back the result to the RAM 1014. The CPU 1012 may also search for information in files, databases, etc. in the recording media. For example, if a plurality of entries, each having an attribute value of the first attribute associated with an attribute value of the second attribute, are stored in the recording medium, the CPU 1012 may search for an entry among said plurality of entries that matches the condition specified for the attribute value of the first attribute and read the attribute value of the second attribute value stored in said entry, thereby obtaining the attribute value of the second attribute associated with the first attribute that satisfies the predetermined condition.

The program or software module described above may be stored in the computer 1000 or a computer-readable storage medium disposed near the computer 100. In addition, a recording medium such as a hard disk or RAM provided in a server system connected to a dedicated communication network or the Internet may be used as the computer-readable storage medium, whereby the program can be provided to the computer 1000 over a network.

The blocks in the flowchart and block diagram in the present embodiment may represent steps of a process in which an operation is performed or “units” of a device functioning to execute the operation. A specific step and “unit” may be implemented by a dedicated circuit, by a programmable circuit provided along with computer-readable instructions stored on a computer-readable storage medium, and/or by a processor provided along with computer-readable instructions stored on a computer-readable storage medium. The dedicated circuit may include digital and/or analog hardware circuits and may include integrated circuits (ICs) and/or discrete circuits. The programmable circuit may include a reconfigurable hardware circuit such as a field programmable gate array (FPGA) and programmable logic array (PLA) including logical or (OR), logical and (AND), exclusive logical or (XOR), negative or (NOR), and other logical operators, a flip-flop, a register, and a memory element.

The computer-readable storage medium may include any tangible device capable of storing instructions to be executed by a suitable device. Therefore, the computer-readable storage medium with instructions stored therein will include a product containing instructions that can be executed to create means for performing the operations specified in the flowchart or block diagram. Examples of the computer-readable storage media may include electronic, magnetic, optical, electromagnetic, and semiconductor storage media. More specific examples of the computer-readable storage media include floppy® (registered trademark) disks, diskettes, hard disks, random access memory (RAM), read-only memory (ROM), erasable programmable read-only memory), electrically erasable memory (EPROM or flash programmable read-only memory (EEPROM), static random access memory (SRAM), compact disc read-only memory (CD-ROM), digital versatile disc (DVD), Blu-ray® (registered trademark) discs, memory sticks, integrated circuit cards, etc.

The computer-readable instructions may include assembler instructions, instruction set architecture (ISA) instructions, machine instructions, machine dependent instructions, microcode, firmware instructions, state-setting data, or source code or object code written in any combination of one or more programming languages, including Smalltalk, JAVA (registered trademark), object-oriented programming languages such as C++, and conventional procedural programming languages such as “C” programming language or similar programming languages.

The computer-readable instructions may be provided to a processor of a general-purpose computer, a special-purpose computer or an any other programmable data processing device or to a programmable circuit, locally or via a wide area network (WAN), such as a local area network (LAN), the Internet, etc., in order for the processor of the general-purpose computer, the special-purpose computer or the any other programmable data processing device, or the programmable circuit to execute computer-readable instructions to generate means for executing operations specified in a flowchart or block diagram Examples of the processor include computer processors, processing units, microprocessors, digital signal processors, controllers, microcontrollers, etc.

### EXPLANATION OF REFERENCE NUMERALS

1 Charged particle beam device
19 Control device
20 Electron beam control unit
21 Focused ion beam control unit
22 Drive control unit
23 Memory unit
24 Control unit
31 Observation image generation unit
32 Calculation unit
33 Correction unit

1. A control method for a charged particle beam device for processing a cross-section of a sample at a processing angle, which is a predetermined angle, by irradiating a sample S, in which a plurality of layers is laminated, with a focused ion beam, the control method comprising:
an image generation step of irradiating the sample with an electron beam, detecting secondary electrons or reflected electrons generated from the sample, and generating an observation image of a cross-section of the sample based on the results of detection;
an angle deviation calculation step of calculating angle deviation between an angle of the cross-section and the processing angle; and
a control step of controlling orientation of the sample or a direction of radiation with the electron beam so that the angle deviation calculated in the angle deviation calculation step is eliminated.

2. The control method according to claim 1, wherein the observation image comprises a plurality of layers including an observation target layer, which is a layer of target of observation;
the control method further comprises a thickness calculation step of calculating thickness of the observation target layer based on an image of the cross-section, and the angle deviation calculation step calculates the angle deviation by Formula (1), where Ld represents thickness of the observation target layer that is calculated, Lm represents a design value of thickness of the observation target layer, and θ represents the angle deviation,
θ=cos⁻¹ (Lm/Ld) . . . Formula (1).

3. The control method according to claim 1, further comprising:
a first processing step of executing processing of a cross-section of the sample while irradiating the sample with the focused ion beam;
a second processing step of determining that there is a layer change in case, in the observation image obtained in the first processing step, two layers above and below or left and right are mixed and stopping processing in the first processing step to process a cross-section of the sample by a predetermined amount with the focused ion beam; and
a layer edge position calculation step of calculating a first layer edge position, which is a position of a layer change based on the observation image obtained before the second processing step, and a second layer edge position, which is a position of layer change based on the observation image obtained after the second processing step,
wherein the angle deviation calculation step calculates the angle deviation by Formula (2), where Lp represents a position deviation, which is a distance between the first layer edge position and second layer edge position that are calculated in the layer edge position calculation step, Lf represents the predetermined amount, and θ represents the angle deviation,
θ=tan⁻¹ (Lf/Lp) . . . Formula (2).

4. The control method according to claim 1, comprising:
a processing step of executing processing of a cross-section of the sample while irradiating the sample with the focused ion beam;
a stopping step of determining that there is a layer change in case, in the observation image obtained in the processing step, two layers above and below or left and right are mixed and stopping processing in the processing step;
an image generation step of generating a surface image and a transmission image of the sample as the observation image by changing acceleration voltage of the electron beam; and
a layer edge position calculation step of calculating a first layer edge position, which is a position of a layer change, based on the surface image, and a second layer edge position, which is a position of a layer change, based on the transmission image,
wherein the angle deviation calculation step calculates the angle deviation by Formula (3), where Lr represents a position deviation, which is a distance between the first layer edge position and the second layer edge position that are calculated in the layer edge position calculation step, Lt represents an amount of transmission of the electron beam from the surface of the sample, and θ represents the angle deviation,
θ=tan⁻¹ (Lt/Lr) . . . Formula (3).

5. A charged particle beam device comprising:
a focused ion beam column configured to irradiate a sample, in which a plurality of layers is laminated, with a focused ion beam to process a cross-section of the sample at a processing angle, which is a predetermined angle;
an ion beam column configured to irradiate the sample with an electron beam;
an electron detector configured to detect secondary electrons or reflected electrons generated from the sample;
an observation image generation unit configured to generate an observation image, which is an image of a cross-section of the sample, based on a signal output from the electron detector;
a calculation unit configured to calculate a angle deviation between an angle of the cross-section and the processing angle based on the image; and
a correction unit configured to control orientation of the sample or a direction of radiation with the electron beam so that the angle deviation calculated in the calculation unit is eliminated.

6. A program causing a computer that controls a charged particle beam device that irradiates a sample, in which a plurality of layers is laminated, with a focused ion beam to process a cross-section of the sample at a processing angle, which is a predetermined angle, to execute processing operations of:
irradiating the sample with an electron beam;
detecting secondary electrons or reflected electrons generated from the sample;
generating an observation image of a cross-section of the sample based on results of detection;
calculating angle deviation between an angle of the cross-section and the processing angle based on the observation image; and
controlling orientation of the sample or a direction of radiation with the electron beam so that the angle deviation that is calculated is eliminated.
